(19) United States
(12) Patent Application Publication
(10) Pub. No.: US 2025/0072095 A1
(43) Pub. Date: Feb. 27, 2025

(54) TERMINAL STRUCTURE WITH OPTIMIZED RELIABILITY FOR POWER DEVICE, PREPARATION METHOD THEREFOR AND APPLICATION THEREOF, POWER DEVICE AND PREPARATION METHOD THEREFOR

(71) Applicant: Huahong ZealCore Electronics Technology Co.,Ltd, Shanghai (CN)

(72) Inventors: Yimin WAN, Shanghai (CN); Xiaojun WANG, Shanghai (CN); Qinghai MA, Shanghai (CN); Xiuzhong WANG, Shanghai (CN); Rong CHEN, Shanghai (CN); Haiming BAO, Shanghai (CN)

(21) Appl. No.: 18/762,561

(22) Filed: Jul. 2, 2024

Related U.S. Application Data
(63) Continuation-in-part of application No. PCT/CN2024/084118, filed on Mar. 27, 2024.

(30) Foreign Application Priority Data
Aug. 25, 2023 (CN) 202311079046.2

(51) Int. Cl. H01L 29/51; H01L 21/285; H01L 29/40; H01L 29/417

(52) U.S. Cl. CPC H01L 29/518; H01L 21/28556; H01L 29/401; H01L 29/41741

(57) ABSTRACT

A terminal structure with optimized reliability for a power semiconductor device, a preparation method therefor, application thereof, a power device and a preparation method therefor are provided. The terminal structure includes a phosphorus-doped silicon oxide layer, a silicon nitride layer, a silicon-rich silicon nitride semi-insulating layer, an undoped silicon dioxide layer, and an organic medium layer. The silicon-rich silicon nitride semi-insulating layer is of an alternating superposition structure of a silicon-rich silicon nitride layer and an ultra-thin silicon nitride barrier layer. The terminal structure effectively prevents external moisture from invading the power device, which improves the robustness of the power device under a moisture condition. The multi-layer silicon-rich silicon nitride is used as a semi-insulating layer, which makes an electric field on a surface of the power device evenly distributed in gradient, prevents the electric field from being gathered at a device terminal.

### CROSS-REFERENCE TO RELATED APPLICATION

This application is a continuation-in-part of International Application No. PCT/CN2024/084118, filed on Mar. 27, 2024, which claims the priority of Chinese Patent Application No. CN202311079046.2 filed with the China National Intellectual Property Administration on Aug. 25, 2023, and entitled “Power device having terminal structure with optimized reliability and manufacturing method for power device”. Both of the aforementioned applications are hereby incorporated by reference in their entireties.

### TECHNICAL FIELD

The present disclosure relates to the technical field of structural design and manufacture of semiconductor devices, in particular to a terminal structure with optimized reliability for a power semiconductor device, a preparation method for the terminal structure, and application of the terminal structure, and a power device and a preparation method therefor.

### BACKGROUND

With the advancement of power electronic technology, power semiconductor devices are being utilized in a wide range of applications. This necessitates continuous enhancement in the performance and reliability of these devices. In recent years, there has been an increasing emphasis on utilizing power semiconductor devices in harsh environments, which has led to more stringent testing conditions before they leave the factory. Currently, the reverse bias test (H3TRB) conducted under conditions of high humidity, high temperature, and high voltage reverse bias has emerged as a fundamental testing approach for validating the reliability of power semiconductor devices.

In the realm of power semiconductor device design and production, the terminal and passivation layer play crucial roles in determining the device's reliability. The design of terminals and structure of passivation layers influence parameters such as leakage current and breakdown electric field during H3TRB testing. Consequently, optimizing terminal design and passivation layer structure is one of crucial elements in optimizing the overall reliability of the device.

The terminal of a power semiconductor device is highly susceptible to high electric fields, necessitating a reliable terminal design to prevent breakdown caused by electric field gathered at the device terminal, at low voltages. This device terminal structure typically includes semi-insulating and insulating materials, with common insulating layers such as polyimide or undoped SiO₂. To prevent the infiltration of sodium and potassium ions through the oxide layer, diffusion barriers like silicon nitride and phosphorus or boron-doped SiO₂ layers are employed to enhance device protection against ion contamination. The semi-insulating layer can be adjusted in conductivity to achieve a continuous reduction in the surface potential of the power semiconductor device, thereby lowering the risk of terminal breakdown under high voltages.

The intrusion of moisture into the power semiconductor device under conditions of high temperature and high humidity is an important aspect affecting the device's reliability when the power semiconductor device module is actually used. During H3TRB testing, the combination of high voltage, high temperature and high humidity expedites the process of infiltration of moisture into the device. After long-term infiltration of moisture into the power device module, it is a challenge to remove the moisture from the module at high temperature, which causes the moisture to gather accumulated inside the device module. Temperature variations that follow in the operation process result in moisture condensation, which profoundly modifies the material's characteristics and ultimately causes device failure. Throughout this process, the silicon nitride layer reacts with the infiltrating moisture at high voltage, and is oxidized. One the one hand, the oxidation process diminishes the density of the silicon nitride, reducing its effectiveness as a passivation layer. Moreover, the moisture penetrates further into an underlying aluminum layer, elevating the device's leakage current and eventually causing breakdown. On the other hand, the oxidation process triggered by electrochemical reactions alters the structures of the silicon nitride and aluminum layers, inducing heightened local stress in the device terminal region and leading to mechanical deterioration of the device terminal.

A semiconductor device in the prior art in this field, includes a semiconductor wafer and a passivation layer stack formed on a surface of the wafer, and the passivation layer employs an amorphous semi-insulating layer, a first nitride layer, an intermediate layer and a second nitride layer. In such a structure, it is not considered that the invasion of moisture into the nitride layer causes the rise of the leakage current of the device and eventually leads to breakdown. A semiconductor device with another structure includes a semi-insulating polysilicon layer, a silicon nitride layer, and a silicon dioxide layer. Although the invasion of moisture into the silicon nitride layer has been considered in such a structure, the introduction of the semi-insulating polysilicon layer may increases the leakage current of the device, thereby leading to the increase of the power consumption of the device and the reduction of the lifetime of the device, while increasing the process complexity and the device cost.

### SUMMARY

In the prior art, challenges have been identified, including issues related to the limited effectiveness of robustness due to moisture ingress and the complex manufacturing procedures associated with power semiconductor device production. In order to simply the manufacturing process of the power semiconductor device while ensuring the robustness of the device terminal for moisture invasion, a terminal structure with optimized reliability for a power device, a preparation method for the terminal structure, application of the terminal structure, a power device and a preparation method for the power device are provided by the present disclosure.

The present disclosure relates to a structure design and manufacturing method for a power semiconductor device, including a wafer, and a passivation layer structure formed on the device terminal on the wafer surface. This terminal structure includes a phosphorous-doped silicon oxide layer, a silicon nitride layer, a silicon-rich silicon nitride semi-insulating layer, an undoped silicon dioxide layer, and an organic medium layer, arranged in sequence from the wafer's surface to a direction gradually away. The silicon-rich silicon nitride semi-insulating layer is of a layered structure in which a silicon-rich silicon nitride layer and a silicon nitride layer are alternately arranged. As per the current disclosure, it is possible to diminish leakage current, enhance device reliability, streamline the manufacturing process, and achieve cost savings.

In the power semiconductor device of the present disclosure, a semiconductor wafer is provided. The wafer may be made of silicon, silicon carbide, gallium nitride or other wide bandgap semiconductor materials. First, a metal-oxide semiconductor (MOS) structure is formed on a front surface of the wafer, and the manufacturing and process methods of the MOS structure until the end of the top metal process of the MOS structure are well known to those skilled in the art. Then, a phosphorus-doped silicon oxide layer with a thickness of 1000-2000 Å is deposited on the top metal by High Density Plasma Chemical Vapor Deposition (HDP CVD). On the one hand, the phosphorous-doped silicon oxide layer can relieve the strain of a subsequent silicon nitride layer on a substrate; on the other hand, the doped phosphorus impurity can form ion traps to improve the protection of the device against ion pollution. Afterwards, a silicon nitride layer with a thickness of 1500-2000 Å is deposited on the silicon dioxide layer by Plasma-Enhanced Chemical Vapor Deposition (PECVD), which can prevent the substrate from mechanical damage and the invasion of metal ions. To alleviate the strain on the silicon nitride layer, an approach involving alternating deposition through PECVD at differing frequencies can be utilized. This method entails applying a high frequency for duration of 11-13 seconds followed by a low frequency for duration of 5-7 seconds. The ratio of the high frequency duration to the low frequency duration falls within the range of 0.60-0.70, resulting in a stress level of the deposited Si₃N₄ layer that is below 50 MPa. The frequencies employed could be 13.56 MHz for the high frequency and 100 kHz for the low frequency.

A silicon-rich silicon nitride semi-insulating layer is on the silicon nitride layer. The silicon-rich silicon nitride semi-insulating layer is of a layered structure in which silicon-rich silicon nitride layer and silicon nitride layer are alternately arranged. The silicon-rich silicon nitride and the silicon nitride are sequentially deposited by PECVD, where the thicknesses of silicon-rich silicon nitride and silicon nitride deposited once are 250-500 Å and 10-50 Å, respectively. The ultimate thickness of the silicon-rich silicon nitride semi-insulating layer is 9000-11000 Å. In the silicon-rich silicon nitride layer, the content of silicon gradually decreases with the deposition, and finally remains the same as that in the silicon nitride. The content of silicon is adjusted by sputtering power of a Si target and a Si₃N₄ target in PECVD. Due to the existence of silicon, the property of the silicon-rich silicon nitride is close to that of the semiconductor, and the conductivity of the silicon-rich silicon nitride can be adjusted by adjusting the content of silicon. The ultra-thin silicon nitride barrier layer serves to restrict the inter-diffusion of silicon among different silicon-rich silicon nitride layers. The silicon-rich silicon nitride layer and the ultra-thin silicon nitride barrier layer are alternately arranged to form a multi-layer structure to serve as a semi-insulating layer. On the one hand, the continuous drop of surface potential can be achieved by adjusting the conductivity of different layers in the multi-layer structure formed by alternately arrangement of silicon-rich silicon nitride layer and ultra-thin silicon nitride barrier layer, thereby making an electric field on the surface of the device evenly distributed in gradient, and effectively eliminating the breakdown of the device under a high voltage. On the other hand, it is helpful to provide a fixed interface charge on the surface layer of the device, so as to provide a circulation path for trap charges accumulated on the surface of the device.

An undoped silicon dioxide layer is on the silicon-rich silicon nitride semi-insulating layer, which is fabricated using HDP CVD and typically ranges in thickness of 3500-5000 Å. The undoped silicon dioxide layer exhibits a strong moisture-blocking capability, while also forming a hydrogen-oxygen bond that promotes robust adhesion of a subsequent organic medium layer, thus avoiding the unreliable adhesion of the organic medium layer directly deposited on the silicon nitride layer. Finally, an organic medium layer is deposited on the undoped silicon dioxide layer, which includes materials such as polyimide and organic silicon, effectively blocking external moisture from the device.

A terminal structure of the power semiconductor device according to the present disclosure, including a phosphorus-doped silicon oxide layer, a silicon nitride layer, a silicon-rich silicon nitride semi-insulating layer, an undoped silicon dioxide layer and an organic medium layer, can effectively prevent external moisture from invading into the device, thereby improving the robustness of the device under a moisture condition. The silicon-rich silicon nitride multilayer is introduced as a semi-insulating layer, which makes an electric field on the surface of the power semiconductor device evenly distributed in gradient, thereby preventing the electric field from being gathered at the device terminal, and enhancing the breakdown resistance of the device under a high voltage. The design of the terminal structure effectively optimizes the reliability of the device under a harsh operating environment.

The silicon-rich silicon nitride semi-insulating layer according to the present disclosure is composed of a silicon-rich silicon nitride and an ultra-thin silicon nitride barrier layer. The conductivity of the silicon-rich silicon nitride is adjusted by controlling the content of silicon in the silicon-rich silicon nitride, and the ultra-thin silicon nitride barrier layer is used as a shielding layer to prevent the diffusion of silicon between different silicon-rich silicon nitride layers. The deposition of the silicon-rich silicon nitride semi-insulating layer material can be conduct in the same PECVD reaction chamber as the silicon nitride layer, which simplifies the process flow and saves the manufacturing cost of the device.

The phosphorus-doped silicon oxide layer and the undoped silicon dioxide layer are provided in the present disclosure. The phosphorus-doped silicon oxide layer can effectively relieve the strain of the subsequent silicon nitride layer on the substrate, and meanwhile, the doped phosphorus can form an ion trap to improve the protection of the device against ion pollution. The undoped silicon dioxide layer can effectively block moisture; in addition, the hydrogen-oxygen bond in the undoped silicon dioxide layer can ensure that the subsequent organic medium layer has good adhesion, thus avoiding the unreliable adhesion of the organic medium layer directly deposited on the silicon nitride layer.

### BRIEF DESCRIPTION OF THE DRAWINGS

FIG. 1 is a structural schematic diagram of a power device in the prior art;

FIG. 2 is a structural schematic diagram of a power device according to an embodiment of the present disclosure;

FIG. 3 is a schematic diagram of a composite structure of a silicon-rich silicon nitride semi-insulating layer in a power device according to an embodiment of the present disclosure in FIG. 2, in which an arrow direction denotes a material deposition direction in a silicon-rich silicon nitride semi-insulating layer.

In the drawings:

1—metal layer; 2—gate-source isolation layer; 3—N+ source region; 4—polycrystalline gate; 5—P-type doped region; 6—gate oxide layer; 7—N-drift region; 8—phosphorus-doped silicon dioxide layer; 9—silicon nitride layer; 10—silicon-rich silicon nitride semi-insulating layer; 11—undoped silicon dioxide layer; 12—organic medium layer; 13—silicon-rich silicon nitride layer; 14—ultra-thin silicon nitride barrier layer.

### DETAILED DESCRIPTION OF THE EMBODIMENTS

The specific embodiments of the present disclosure are given below with the accompanying drawings, and the technical solution in the present disclosure is described clearly and completely, but the present disclosure is not limited to the following embodiments. Apparently, the described embodiments are merely a part rather than all of the embodiments of the present disclosure. Advantage and features of the present disclosure will become more apparent from the follow description and claims. It should be noted that the drawings are all in a very simplified form and all use inaccurate ratios, which are only used for the purpose of conveniently and clearly explaining the embodiment of the present disclosure. All other embodiments obtained by a person of ordinary skill in the art based on the embodiments of the present disclosure without creative efforts shall fall within the scope of protection of the present disclosure.

The present disclosure can be embodied in different forms and should not be construed as limited to the embodiments set forth herein. Rather, these embodiments are provided so that this disclosure will be thorough and complete, and will fully convey the scope of the present disclosure to those skilled in the art. In the drawings, the dimensions and relative dimensions of layers and regions may be exaggerated for clarity, with the same reference numerals indicating the same elements throughout. In the description of the present disclosure, it needs to be understood that the orientation or positional relationship indicated by terms “center”, “top”, “bottom”, “left”, “right”, “vertical”, “horizontal”, “inside” and “outside” is based on the orientation or positional relationship shown in the drawings only for convenience of description of the present disclosure and simplification of description rather than indicating or implying that the device or element referred to must have a particular orientation, be constructed and operate in a particular orientation, and thus are not to be construed as limiting the present disclosure. Furthermore, the terms “first”, “second” and “third” are used for descriptive purposes only and are not to be construed as indicating or implying relative importance.

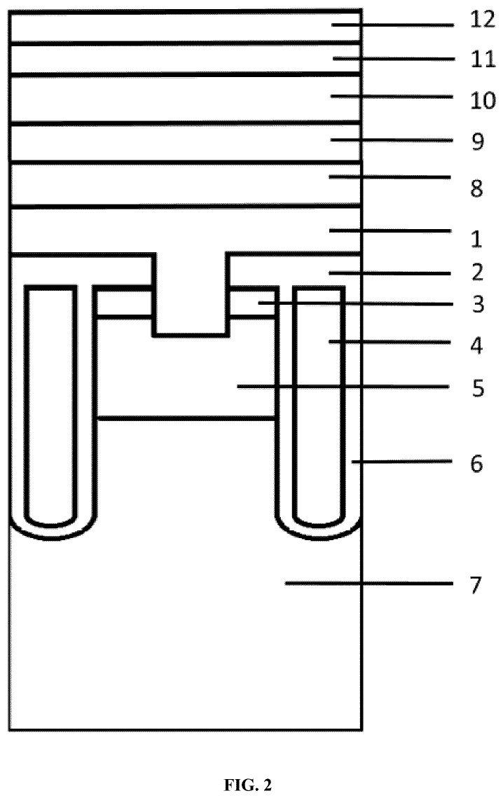

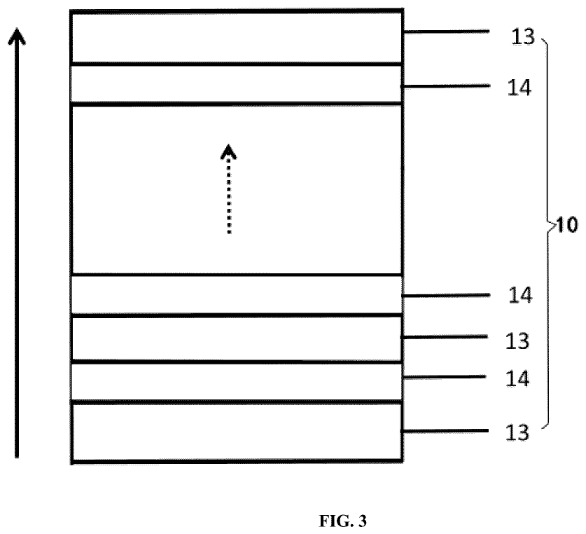

The specific embodiment of the present disclosure is as follows. FIG. 2 and FIG. 3 are structural diagrams of the present disclosure, and the dimensions in the drawings do not constitute a proportional relationship. A region shown in FIG. 2 includes a metal layer 1, a gate-source isolation layer 2, a N+source region 3, a polycrystalline gate 4, a P-type doped region 5, a gate oxide layer 6, a N-drift region 7, a phosphorus-doped silicon dioxide layer 8, a silicon nitride layer 9, a silicon-rich silicon nitride semi-insulating layer 10, a undoped silicon dioxide layer 11, and an organic medium layer 12. Regions 1 to 7 form a MOS structure. Regions 8, 9, 10, 11 and 12 are a terminal structure of a power semiconductor device, including a passivation layer, a semi-insulating layer, and an organic medium layer. A silicon-rich silicon nitride semi-insulating layer is shown in FIG. 3, including a silicon-rich silicon nitride layer 13, an ultra-thin silicon nitride barrier layer 14 which are alternately arranged.

An arrow direction in FIG. 3 denotes a material deposition direction in a silicon-rich silicon nitride semi-insulating layer.

In the power device structure shown in FIG. 2, Region 1 is an aluminum-copper metal layer, which serves as a metal interconnection line. Region 2 is a gate-source isolation layer composed of silicon dioxide and boron-phosphorus doped silicon dioxide. Region 3, Region 5 and Region 7 are N-type silicon or P-type silicon.

Region 4 is a gate formed by polysilicon, which can withstand high temperature and has self-alignment function. Region 6 is a gate oxide layer composed of a high-quality silicon dioxide layer. Regions 1 to 7 form a MOS structure. Regions 8, 9, 10, 11 and 12 are a terminal structure of a power semiconductor device, including a passivation layer, a semi-insulating layer, and an organic medium layer. A specific structure of a silicon-rich silicon nitride semi-insulating layer 10 shown in FIG. 3 is a multi-layered composite layer, including a silicon-rich silicon nitride layer 13 and an ultra-thin silicon nitride barrier layer 14. The silicon-rich silicon nitride layer 13 and the ultra-thin silicon nitride barrier layer 14 are alternately stacked to form the silicon-rich silicon nitride semi-insulating layer 10. An arrow direction in FIG. 3 denotes a material deposition direction in a silicon-rich silicon nitride semi-insulating layer.

In the structure shown in FIG. 2, a phosphorus-doped silicon oxide layer 8, a silicon nitride layer 9, a silicon-rich silicon nitride semi-insulating layer 10, an undoped silicon dioxide layer 11 and an organic medium layer 12 constitute the terminal structure of the semiconductor power device. The terminal structure effectively prevents the external moisture from invading into the device, thereby improving the robustness of the device under the moisture condition. The silicon-rich silicon nitride multilayer 10 is introduced as a semi-insulating layer, and the conductivity of the silicon-rich silicon nitride is adjusted by controlling the content of silicon in the silicon-rich silicon nitride. The ultra-thin silicon nitride barrier layer serves to restrict the inter-diffusion of silicon among different silicon-rich silicon nitride layers, such that the electric field on the surface of the power semiconductor device is uniformly distributed in gradient, thereby preventing the electric field from being gathered at the device terminal and enhancing the breakdown resistance of the device under the high voltage. The design of the terminal structure effectively optimizes the reliability of the device under a harsh operating environment. The deposition of the silicon-rich silicon nitride semi-insulating layer material can be conduct in the same PECVD reaction chamber as the silicon nitride layer, which simplifies the process flow and saves the manufacturing cost of the device.

A phosphorus-doped silicon oxide layer 8 and the undoped silicon dioxide layer 11 are provided according to the present disclosure. The phosphorus-doped silicon oxide layer 8 can effectively relieve the strain of the subsequent silicon nitride layer on the substrate, and meanwhile, the doped phosphorus can form an ion trap to improve the protection of the device against ion pollution. The undoped silicon dioxide layer 11 can effectively block moisture; in addition, the hydrogen-oxygen bond in the undoped silicon dioxide layer 11 can ensure that the subsequent organic medium layer 12 has good adhesion, thus avoiding the unreliable adhesion of the organic medium layer directly deposited on the silicon nitride layer 9.

The manufacturing process methods of these structures are illustrated below.

Firstly, a MOS structure is formed. The above MOS structure is formed and manufactured on an N-type monocrystalline silicon or a wide bandgap semiconductor such as SiC substrate. The substrate is not limited to the above, but is preferably a wide bandgap semiconductor material. The conventional manufacturing method for the MOS structure is well known to those skilled in the art.

As shown in FIG. 2, an N-type drift region 7 is formed on the SiC substrate by PECVD. Then, SiO₂ with a thickness of 4000 Å is deposited on the drift region 7 as a hard mask layer for subsequent trench gate etching.

Photoresist is spin-coated on the hard mask layer, and then is subjected to baking, exposure and development, and the SiO₂ is etched. Then, the SiO₂ is used as hard mask to etch an N-drift region, and a trench with a depth of about 5 microns is formed in partial region of the N-drift region as a trench of a gate.

After removing a sacrificial oxide layer, a high-quality silicon oxide layer is grown by HDP CVD as a gate oxide layer 6.

A polysilicon layer with a thickness of 3000 Å is deposited by LPCVD process, and after etching the polysilicon, a trench type polysilicon gate 4 is formed.

A P-type doped region 5 is formed by boron ion implantation and drive-in at a first temperature, where the first temperature may be 1150° C.

An N+source region 3 is formed in partial P-type doped region 5, close to the gate, of a silicon trench by As ion implantation and drive-in at a second temperature, where the second temperature may be 950° C.

Ethyl orthosilicate and boron-phosphorus doped silicon dioxide (TEOS+BPSG) are deposited, and then contact lithography is conducted to form a gate-source isolation layer 2.

Metal AlCu is deposited using magnetron sputtering, and a front metal layer 1 is formed after metal etching, thus completing the manufacture of the MOS structure.

A manufacturing process of the terminal structure is sequentially conducted. Firstly, a phosphorus-doped silicon oxide layer 8 with a thickness of 2000 Å is deposited on the front metal layer 1 by HDP CVD. The silicon oxide deposited by the HDP CVD process has low process temperature and good step coverage.

Further, a silicon nitride layer 9 with a thickness of 2000 Å is deposited on the phosphorus-doped silicon oxide layer 8 by PECVD. In order to reduce the strain of the silicon nitride Si₃N₄ layer 9, alternate deposition by PECVD at a first frequency and a second frequency is adopted, in which the first frequency duration and the second frequency duration are 13 s and 7 s, respectively, a ratio of the first frequency duration to the second frequency duration is 0.65, and the stress of the deposited Si₃N₄ layer is about 30 MPa, where the first frequency and the second frequency may be 13.56 MHz and 100 kHz, respectively.

A multilayer composite silicon-rich silicon nitride semi-insulating layer 10 formed by the silicon-rich silicon nitride 13 and an ultra-thin silicon nitride barrier layer 14 alternately arranged and superimposed is deposited on the Si₃N₄ layer 9 by PECVD. The thicknesses of the silicon-rich silicon nitride and the ultra-thin silicon nitride barrier layer deposited once are 300 Å and 25 Å, respectively, and a final thickness of the silicon-rich silicon nitride semi-insulating layer is 10000 Å. In the silicon-rich silicon nitride layer, the content of silicon is adjusted by the sputtering power of a Si target and a Si₃N₄ target in PECVD, and the content of Si in the silicon-rich silicon nitride layer gradually decreases, which is finally consistent with that in the ultra-thin silicon nitride barrier layer.

By spin-coating photoresist on the Si₃N₄ layer 9, and etching Si₃N₄ after baking, exposure and development, a PAD region of the power device is formed. Afterwards, the power device is annealed for 30 min at a temperature environment of 400° C., which makes the passivation layer structure more compact and releases metal stress and residual electrons from etching.

An undoped silicon dioxide layer 11 with a thickness of 4000 Å is grown on a multi-layer composite silicon-rich silicon nitride semi-insulating layer by HDP CVD.

Polyimide is spin-coated on the undoped silicon dioxide layer 11, baked in an oxygen-free environment at 425° C. for 60 minutes, and is finally cured to form an organic medium layer 12. The thickness of the cured polyimide is 10 μm. The all manufacturing of the device of the present disclosure is completed.

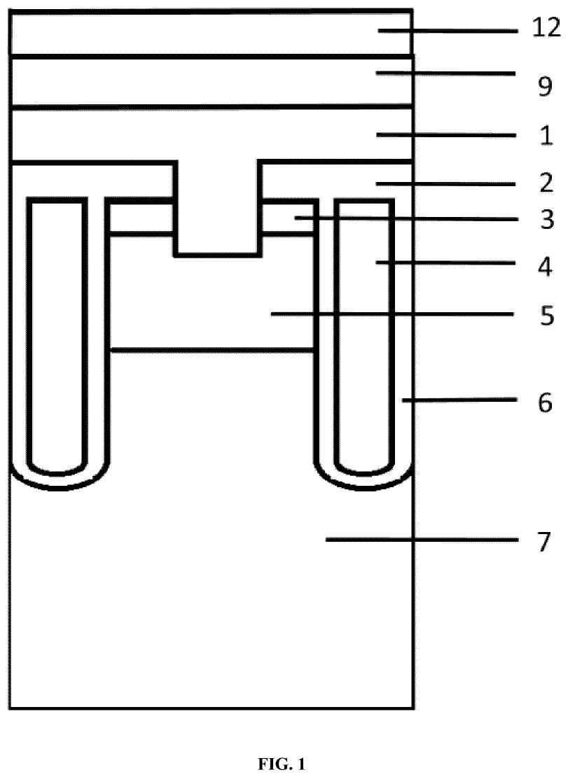

FIG. 1 is s structure of a power device in the prior art, its manufacturing method is basically the same as the above embodiment, except for the terminal structure in the present disclosure.

An existing comparative structure shown in FIG. 1 and the structure of the present disclosure shown in FIG. 2 are compared and tested in performance. And H3TRB reliability testing is conducted on the power devices provided by the embodiment of the present disclosure and the comparative structure, which includes the tests of leakage current changing over time and leakage current changing with BV (breakdown voltage) withstanding voltage. The results are as follows.

In the power semiconductor device provided by the embodiment of the present disclosure, with the increase of BV, the leakage currents are 10 nA, 10 nA and 10 nA at 0.5 BV, 0.8 BV and 1.0 BV; and the leakage currents of H3TRB test for 1000 hours, 1500 hours and 3000 hours are 0.2 mA, 0.2 mA and 0.2 mA, respectively.

In the power device with the comparative structure, with the increase of BV, the leakage currents are 0.1 mA, 1 mA and 10 mA at 0.5 BV, 0.8 BV and 1.0 BV; and the leakage currents of H3TRB test for 1000 hours and 1500 hours are 0.5 mA and 10 mA, respectively, and after H3TRB test for 3000 hours, obvious burn points have appeared on the surface of the power semiconductor device, which indicates that the power semiconductor device has been damaged by breakdown.

Result analysis is as follows.

Based on the above detection results, it is clear that compared with the prior art, the power device with the terminal structure according to the embodiment of the present disclosure can significantly reduce the leakage current of the device. In the reliability H3TRB test, the leakage current of the device is almost unchanged until 3000 hours, and the reliability of the device is significantly improved.

It should be understood that the above embodiments are merely used for illustrating the technical idea and features of the present disclosure, with the purpose of enabling those skilled in the art to understand the content of the present disclosure and implement the content accordingly, and the scope of protection of the present disclosure is limited hereto. Any equivalent substitutions or modifications made according to the spirit essence of the present disclosure shall fall within the scope of the claims of the present disclosure.

1. A terminal structure—for a power semiconductor device, wherein the terminal structure comprises a phosphorus-doped silicon oxide layer, a silicon nitride layer, a silicon-rich silicon nitride semi-insulating layer, an undoped silicon dioxide layer, and an organic medium layer in sequence from bottom to top.

2. The terminal structure according to claim 1, wherein the silicon-rich silicon nitride semi-insulating layer is a composite layer formed by alternately superposing multiple layers of a silicon-rich silicon nitride layer and an ultra-thin silicon nitride barrier layer.

3. The terminal structure according to claim 2, wherein a single silicon-rich silicon nitride layer and a single ultra-thin silicon nitride barrier layer have thicknesses of 250-500 Å and 10-50 Å, respectively, and a total thickness of the silicon-rich silicon nitride semi-insulating layer is 9000-11000 Å.

4. The terminal structure according to claim 1, wherein the phosphorus-doped silicon oxide layer has a thickness of 1000-2000 Å;
the silicon nitride layer has a thickness of 1500-2000 Å;
the undoped silicon dioxide layer has a thickness of 3500-5000 Å; and
the organic medium layer has a thickness of 10 μm.

5. A preparation method for the terminal structure according to claim 1, comprising:
forming the phosphorus-doped silicon oxide layer on a surface of a substrate;
forming the silicon nitride layer on the phosphorus-doped silicon oxide layer;
forming the silicon-rich silicon nitride semi-insulating layer on the silicon nitride layer;
forming the undoped silicon dioxide layer on a surface of the silicon-rich silicon nitride semi-insulating layer; and
spin-coating polyimide on a surface of the undoped silicon dioxide layer, and curing the polyimide to form the organic medium layer.

6. The preparation method according to claim 5, wherein the phosphorus-doped silicon oxide layer is deposited by using a low-temperature high-density plasma chemical vapor deposition (HDP-CVD) method.

7. The preparation method according to claim 5, wherein the silicon nitride layer is formed by using a plasma enhanced chemical vapor deposition (PECVD) process, and the PECVD process is alternate deposition by the PECVD method at a first frequency and a second frequency, wherein the first frequency is higher than the second frequency.

8. The preparation method according to claim 7, wherein in the alternate deposition by the PECVD method at a first frequency and a second frequency, the first frequency duration and the second frequency duration are 11-13 s and 5-7 s, respectively, a ratio of the first frequency duration to the second frequency duration is 0.60-0.70, and stress of the deposited silicon nitride layer is less than 50 MPa.

9. The preparation method according to claim 5, wherein a formation of the silicon-rich silicon nitride semi-insulating layer comprises: sequentially depositing the silicon-rich silicon nitride layer and the silicon nitride layer by plasma enhanced chemical vapor deposition.

10. (canceled)

11. The preparation method according to claim 5, wherein a condition for the curing is baking in an oxygen-free environment at 425° C. for 60 minutes.

12. (canceled)

13. A power device having a terminal structure with optimized reliability, comprising a semiconductor substrate, a metal-oxide semiconductor (MOS) structure and a terminal structure which are sequentially stacked from bottom to top;
wherein the terminal structure comprises a phosphorus-doped silicon oxide layer, a silicon nitride layer, a silicon-rich silicon nitride semi-insulating layer, an undoped silicon dioxide layer, and an organic medium layer in sequence from bottom to top; or
the terminal structure prepared by the preparation method of: forming the phosphorus-doped silicon oxide layer on a surface of a substrate;
forming the silicon nitride layer on the phosphorus-doped silicon oxide layer;
forming the silicon-rich silicon nitride semi-insulating layer on the silicon nitride layer;
forming the undoped silicon dioxide layer on a surface of the silicon-rich silicon nitride semi-insulating layer; and
spin-coating polyimide on a surface of the undoped silicon dioxide layer, and curing the polyimide to form the organic medium layer.

14. The power device according to claim 13, wherein the semiconductor substrate is a Si or a wide bandgap semiconductor.

15. The power device according to claim 14, wherein the semiconductor substrate is a silicon-containing substrate, a silicon carbide substrate, a gallium nitride substrate, a germanium-silicon substrate, or a gallium arsenide substrate.

16. The power device according to claim 13, wherein the MOS structure is a planar MOS or a trench MOS.

17. The power device according to claim 16, wherein when the MOS structure is the trench MOS, a structure of the power device is as follows: the power device is formed on the semiconductor substrate, a drift region is formed on the semiconductor substrate, the drift region is etched to form a trench, the trench is filled with polysilicon, and a gate dielectric layer is used to isolate the polysilicon from the trench substrate; the drift region also has a P-type doped region, a N+ type source region of the power device is located in the P-type doped region, and the polysilicon is isolated from the source region by a gate-source isolation layer; and a surface of the gate-source isolation layer is provided with a front metal layer led out from a front of the gate-source isolation layer.

18. The power device according to claim 16, wherein a preparation method for the trench MOS comprises:
forming a N-drift region on the semiconductor substrate, and depositing a hard mask layer on a surface of the drift region;
spin-coating photoresist on the hard mask layer, etching the hard mask layer after curing and developing the photoresist to pattern the hard mask layer, and using the hard mask layer as a pattern for shielding and etching the N-drift region on the semiconductor substrate, to form a trench in a gate region in the N-drift region;
removing the hard mask layer, and then forming a silicon oxide layer as a gate dielectric layer of the MOS structure;
depositing a polysilicon layer and etching back to fill the trench with polysilicon, so as to form a trench type polysilicon gate;
forming a P-type doped region by ion implantation and drive-in at a first temperature;
forming a source region of the MOS structure by ion implantation and drive-in at a second temperature;
completing deposition of Tetraethyl orthosilicate and boron-phosphorus doped silicon dioxide, and then conducting contact lithography to form a gate-source isolation layer; and
depositing and etching to form front connecting metal;
wherein the hard mask layer is a silicon oxide layer with a thickness of 4000 Å.

19. (canceled)

20. The power device according to claim 18, wherein the polysilicon is deposited using an low pressure chemical vapor deposition (LPCVD) method, and has a deposition thickness of 3000 Å to ensure that the trench is filled, and then the filled polysilicon is etched back until the polysilicon in the trench is flush with a surface of the semiconductor substrate.

21. The power device according to claim 13, wherein the power device comprises a pad region; and the pad region is located in a region, on which silicon-rich silicon nitride semi-insulating layer is not formed, of a surface of a silicon nitride layer in the terminal structure.

22. A preparation method for the power device according to claim 13, comprising:
providing a semiconductor substrate, wherein the semiconductor substrate comprises a front surface, and a back surface opposite to the front surface;
manufacturing a MOS structure on the front surface of the semiconductor substrate; and
preparing the terminal structure on a surface of the MOS structure according to the preparation method of:
forming the phosphorus-doped silicon oxide layer on a surface of a substrate;
forming the silicon nitride layer on the phosphorus-doped silicon oxide layer;
forming the silicon-rich silicon nitride semi-insulating layer on the silicon nitride layer;
forming the undoped silicon dioxide layer on a surface of the silicon-rich silicon nitride semi-insulating layer; and
spin-coating polyimide on a surface of the undoped silicon dioxide layer, and curing the polyimide to form the organic medium layer.

23. The preparation method according to claim 22, wherein when the power device further comprises a pad region, the preparation of the pad region comprises following steps:
spin-coating photoresist on the region, on which a silicon-rich silicon nitride semi-insulating layer is not formed, of the surface of the silicon nitride layer in the terminal structure, and etching the silicon nitride layer after baking, exposing and developing the photoresist to form the pad region of the power device; and then annealing the power device at 400° C. for 30 min.
